(19) United States
(12) Patent Application Publication
(10) Pub. No.: US 2014/0150856 A1
(43) Pub. Date: Jun. 5, 2014

(54) PHOTOVOLTAIC MODULE

(71) Applicant: Intellectual Discovery Co., Ltd., Gangnam-gu (KR)

(72) Inventors: Seung-Yeop Myong, Seoul (KR); La-Sun Jeon, Seoul (KR)

(73) Assignee: Intellectual Discovery Co., Ltd., Gangnam-gu (KR)

(21) Appl. No.: 13/690,756

(22) Filed: Nov. 30, 2012

(51) Int. Cl. H01L 31/06

(52) U.S. Cl. CPC H01L 31/06
USPC 136/255

(57) ABSTRACT

Disclosed is a photovoltaic module which includes a plurality of stacked unit cells and is encapsulated by an encapsulant and is designed such that an initial short circuit current of the photovoltaic module under standard test conditions is determined by the initial short circuit current of a top cell or a bottom cell among the plurality of the unit cells in accordance with a nominal operating cell temperature of the photovoltaic module.

### CROSS-REFERENCE TO RELATED APPLICATIONS

This application claims the benefit of Korean Patent Application No. 10-2011-0130496 filed on 7 Dec. 2011, which is hereby incorporated by reference.

### FIELD OF THE INVENTION

The present invention relates to a photovoltaic module, and more particularly to current matching in a stacked multi-junction photovoltaic module.

### BACKGROUND OF THE INVENTION

Recently, as existing energy resources like oil and coal and the like are expected to be exhausted, much attention is increasingly paid to alternative energy sources which can be used in place of the existing energy sources. In the alternative energy sources, sunlight energy is abundant and has no environmental pollution. Therefore, more and more attention is paid to the sunlight energy.

A photovoltaic device, that is, a solar cell directly converts sunlight energy into electrical energy. The photovoltaic device mainly uses photovoltaic effect of semiconductor junction. In other words, when light is incident on and absorbed by a semiconductor pin junction doped with p type impurity and n type impurity respectively, light energy generates electrons and holes within the semiconductor and the electron and the hole are separated from each other by an internal field. As a result, a photo-electro motive force is generated at both ends of the pin. junction. Here, if electrodes are formed at both ends of the junction and connected with wires, electric current flows externally through the electrodes and the wires.

Meanwhile, a single-junction photovoltaic device has its own limited attainable performance. Accordingly, a double-junction photovoltaic device or a triple-junction photovoltaic device, each of which has a plurality of stacked unit cells, has been developed, thereby pursuing high efficiency. The double-junction photovoltaic device or the triple-junction photovoltaic device is designated as a stacked multi-junction photovoltaic device.

Regarding the stacked multi-junction photovoltaic device, a light-induced degradation ratio, stabilized efficiency after light illumination and a fill factor of the photovoltaic module may be affected according to a current matching design between the unit cells. Therefore, there is a requirement for a current matching design for optimizing the efficiency of the stacked multi-junction photovoltaic device.

### SUMMARY OF THE INVENTION

An aspect of the present invention is a photovoltaic module which includes a plurality of stacked unit cells and is encapsulated by an encapsulant. A nominal operating cell temperature of the photovoltaic module is equal to or greater than a predetermined value. The photovoltaic module is designed such that an initial short circuit current of the photovoltaic module under standard test conditions is determined depending on an initial short circuit current of a top cell among the plurality of the unit cells.

Another aspect of the present invention is a photovoltaic module which includes a plurality of stacked unit cells and is encapsulated by an encapsulant. A nominal operating cell temperature of the photovoltaic module is lower than and not equal to a predetermined value. The photovoltaic module is designed such that an initial short circuit current of the photovoltaic module under standard test conditions is determined depending on an initial short circuit current of a bottom cell among the plurality of the unit cells.

The predetermined value of the nominal operating cell temperature may be 40° C.

### BRIEF DESCRIPTION OF THE DRAWINGS

FIG. 1 shows a stacked multi-junction photovoltaic module according to an embodiment of the present invention; and

FIG. 2 shows a measurement example of a nominal operating cell temperature for the stacked multi-junction photovoltaic module according to an embodiment of the present invention in a standard reference environment (SRE).

### DETAILED DESCRIPTION OF THE INVENTION

Hereafter, an exemplary embodiment of the present invention will be described in detail with reference to the accompanying drawings. The shapes and sizes and the like of components of the drawings are exaggerated for clarity of the description. It is noted that the same reference numerals are used to denote the same elements throughout the drawings. In the following description of the present invention, the detailed description of known functions and configurations incorporated herein is omitted when it may make the subject matter of the present invention unclear.

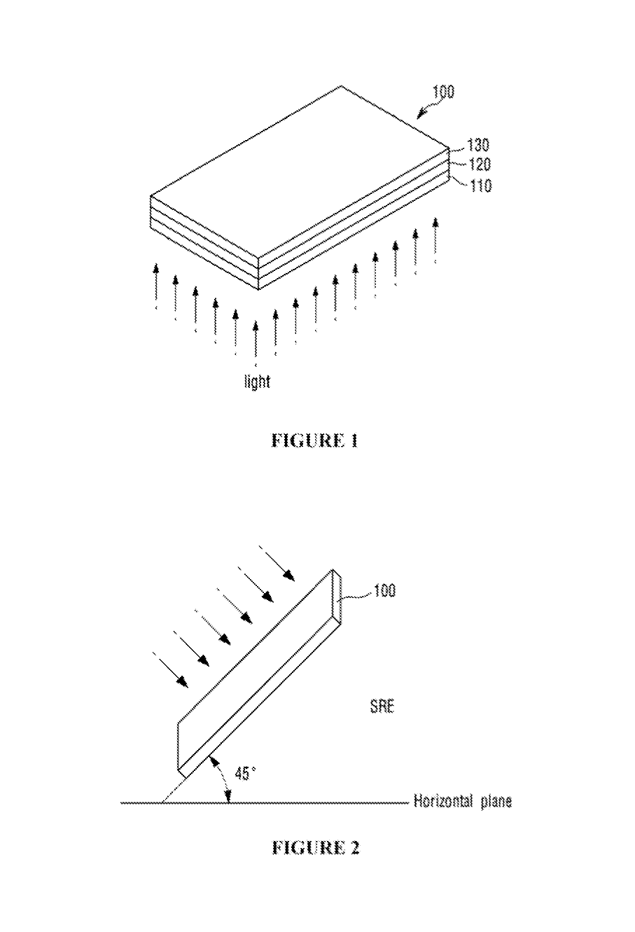

FIG. 1 shows a stacked multi-junction photovoltaic module 100 according to an embodiment of the present invention. The photovoltaic module according to the embodiment of the present invention may include a plurality of stacked unit cells 110, 120 and 130. While FIG. 1 shows the three unit cells 110, 120 and 130, this is only an example and at least two or three unit cells may be included. Each of the stacked unit cells is a basic unit that performs photoelectric conversion.

Each of the plurality of the unit cells 110, 120 and 130 may include any material converting incident light energy into electrical energy. For example, each of the plurality of the unit cells 110, 120 and 130 may include a photoelectric conversion material capable of forming a thin-film type photovoltaic module such as a thin-film silicon solar cell, a compound solar cell, an organic solar cell and a dye sensitized solar cell. Each of the plurality of the unit cells 110, 120 and 130 may also include a photoelectric conversion material capable of forming a bulk type photovoltaic module such as a group □-□ compound solar cell.

A unit cell which is the closest to a side on which light allowing the photovoltaic module 100 to perform the photoelectric conversion is incident is designated as a top cell. A unit cell which is the farthest from a side on which the light is incident is designated as a bottom cell. In FIG. 1, the unit cell 110 which is the closest to a light incident side among the three unit cells 110, 120 and 130 corresponds to the top cell. The unit cell 130 which is the farthest from the light incident side corresponds to the bottom cell.

Therefore, when the photovoltaic module 100 includes two stacked unit cells, a photoelectric conversion layer of the photovoltaic module may be comprised of the top cell 110 and the bottom cell 130.

As shown in FIG. 1, when the photovoltaic module 100 includes three stacked unit cells, the photoelectric conversion layer of the photovoltaic module includes the top cell 110, the bottom cell 130 and a middle cell 120 placed between the top cell 110 and the bottom cell 130.

Each of the stacked unit cells 110, 120 and 130 includes a light absorber which absorbs incident light for the purpose of performing the photoelectric conversion. Here, it is preferable that the closer it is to the light incident side, the larger the optical band gap of the light absorber included in the unit cell is. For example, the optical band gap of the light absorber included in the top cell 110 may be larger than the optical band gap of the light absorber included in the middle cell 120, and the optical band gap of the light absorber included in the middle cell 120 may be larger than the optical band gap of the light absorber included in the bottom cell 130. This is because light with a short wavelength having a high energy density has a short light transmission distance, and a material having a larger optical band gap absorbs more light with a short wavelength.

In the stacked multi-junction photovoltaic module 100, the open circuit voltage of the photovoltaic module 100 is the sum of the open circuit voltages of the stacked unit cells 110, 120 and 130. A short circuit current of the photovoltaic module 100 is the minimum value among the short circuit currents of the stacked unit cells 110, 120 and 130.

The stacked multi-junction photovoltaic module 100 according to the embodiment of the present invention may further include an electrode (not shown) which collects and carries the electric current generated by the photoelectric conversion and may further include a substrate (not shown) in accordance with the embodiment. Also, an intermediate reflector (not shown) may be inserted between the stacked unit cells 110, 120 and 130 so as to maximize light trapping effect by enhancing internal reflection.

The stacked multi-junction photovoltaic module 100 according to the embodiment of the present invention is encapsulated by an encapsulant for the sake of the long-term reliability and endurance of the integrated multi-junction solar cells. In general, a thin-film solar cell is encapsulated by mainly using a coating method in lamination after the electrodes and a cell portion including the photoelectric conversion layer (including a plurality of the unit cells) are covered with ethylvinyl acetate (EVA) film, a front sheet, a back sheet or the like. The module is also manufactured by using cover glass instead of the front sheet or the back sheet. The edge of the module is sealed with silicone, a tape, butyl rubber and the like in order to prevent water from permeating. TPT is generally used as the back sheet which is used to encapsulate the bulk type solar cell module. The TPT is formed in the form of a sandwich by stacking a Poly-Vinyl Fluoride (PVF) film, a Poly-Ethylen Terephthalate (PET) film and a Poly-Vinyl Fluoride (PVF) film in the order listed. Recently, the Poly-Vinyl Fluoride (PVF) of the TPT structure is substituted by Poly-VinyliDene Fluoride (PVDF). The thin-film solar cell module may use a back sheet having aluminum foil inserted thereinto in a basic TPT structure so as to improve humidity resistance.

The foregoing encapsulant and the encapsulating method for the photovoltaic module 100 are only examples. Other encapsulants and/or other encapsulating method may be also used.

An actual operating temperature of the photovoltaic module in outdoors must be considered in a current matching design between the plurality of the unit cells 110, 120 and 130 included in the stacked multi-junction photovoltaic module 100.

For example, when the photovoltaic module has a high operating temperature, the photovoltaic module may be designed such that the short circuit current of the photovoltaic module is determined depending on the short circuit current of the top cell, that is, the unit cell which is the closest to a side on which light is incident among the plurality of the stacked unit cells included in the photovoltaic module. This is because, since a temperature coefficient (an efficiency reduction rate of a photovoltaic device according to a temperature rise by 1° C.) of the photovoltaic module is small, efficiency degradation is small in spite of the temperature rise of the photovoltaic module.

Contrarily, when the photovoltaic module has a low operating temperature, the photovoltaic module may be designed such that the short circuit current of the photovoltaic module is determined depending on the short circuit current of the bottom cell, that is, the unit cell which is the farthest from a side on which light is incident among the plurality of the stacked unit cells included in the photovoltaic module. When the photovoltaic module is designed such that the short circuit current of the photovoltaic module is determined depending on the short circuit current of the bottom cell, the temperature coefficient (an efficiency reduction rate of the photovoltaic device according to a temperature rise by 1° C.) of the photovoltaic module is high and a light-induced degradation ratio of the photovoltaic module is small. Since the photovoltaic module having a low operating temperature is relatively less affected by the temperature coefficient, the photovoltaic module is designed such that the short circuit current of the photovoltaic module is determined depending on the short circuit current of the bottom cell.

A rated power (efficiency) of the photovoltaic module designed in the manner described above is measured indoors according to standard test conditions (STC). STC includes the following conditions:
AM: 1.5 (AIR MASS 1.5)
Irradiance: 1000 w·m⁻²
Temperature of photovoltaic module: 25° C.

However, when the photovoltaic module is installed outdoors and the temperature of the photovoltaic module is higher than 25° C., due to the temperature coefficient of the photovoltaic module, the actual efficiency of the photovoltaic module becomes lower than the rated efficiency of the photovoltaic module according to STC.

In other words, most of light energy absorbed in the photovoltaic module is converted nun heat energy. Accordingly, an actual operating temperature of the photovoltaic module easily becomes higher than 25° C., i.e., the temperature of the photovoltaic module under STC. Therefore, due to the temperature coefficient of the photovoltaic module, the actual efficiency of the photovoltaic module becomes lower than the rated efficiency of the photovoltaic module according to STC.

Because of these problems, when the current matching of the stacked multi-junction photovoltaic module is designed based on 25° C., i.e., the temperature of the photovoltaic module under STC, it is very difficult to obtain a desired efficiency of the module in a practical environment. Therefore, the operating temperature, of the stacked photovoltaic module should be considered in the design of the current matching.

Accordingly, the current matching design a the photovoltaic module according to the embodiment of the present invention is performed by considering nominal operating cell temperature (NOCT) obtained under a standard reference environment (SRE) similar to actual installation conditions of the photovoltaic module as well as by comparing initial short circuit currents under STC. SRE includes the following conditions:
Tilt angle of photovoltaic module: 45° from the horizontal plane
Irradiance: 800 W·m⁻²
Ambient temperature: 20° C.
Wind speed: 1 m·s⁻¹
Electric load: nothing (open circuit state)

FIG. 2 shows a measurement example of nominal, operating cell temperature (NOCT) for the photovoltaic module 100 according to an embodiment of the present invention under SRE. The nominal operating cell temperature corresponds to a temperature at which the photovoltaic module 100 installed on an open rack operates under SRE. The photovoltaic module 100 is used in various practical environments. Therefore, when the current matching design of the stacked multi-junction photovoltaic module 100 is performed in consideration of NOCT measured under SRE similar to the actual installation conditions of the photovoltaic module 100, it is possible to manufacture the photovoltaic module suitable for installation environment thereof.

For this reason, in the photovoltaic module 100 according to the embodiment of the present invention, when NOCT of the photovoltaic module 100 is equal to or greater than a predetermined value, the photovoltaic module 100 may be designed such that the initial short circuit current of the photovoltaic module 100 is determined depending on the initial short circuit current of the top cell under STC. That is, the initial short circuit current of the top cell is designed to be equal to or less than the initial short circuit currents of the remaining unit cells. Additionally, when NOCT of the photovoltaic module 100 is less than a predetermined value, the photovoltaic module 100 may be designed such that the initial short circuit current of the photovoltaic module 100 is determined depending on the initial short circuit current of the bottom cell under STC. That is, the initial short circuit current of the bottom cell is designed to be equal to or less than the initial short circuit currents of the remaining unit cells.

Here, the predetermined value for NOCT is an indicator for the operating temperature of the photovoltaic module in the practical environment and may be determined considering an effect caused by the temperature coefficient and an effect caused by light-induced degradation ratio. For example, the predetermined value for NOCT may be 40° C. When the predetermined value for NOCT is equal to or higher than 40° C., the module generates relatively much heat or radiates relatively less heat When the predetermined value for NOCT is less than 40° C., the module generates less heat or radiates much heat.

In other words, when NOCT of the photovoltaic module 100 is equal to or higher than 40° C., the temperature coefficient has a great influence on the actual efficiency of the photovoltaic module 100. Therefore, the influence caused by the temperature coefficient can be reduced by causing the initial short circuit current of the photovoltaic module 100 to be determined depending on the initial short circuit current of the top cell. As a result, the efficiency degradation according to the temperature coefficient can be reduced in spite of the temperature rise of the photovoltaic module 100.

Further, when NOCT of the photovoltaic module 100 is less than 40° C., the temperature coefficient has a small influence on the actual efficiency of the photovoltaic module 100. Therefore, by causing the initial short circuit current of the photovoltaic module 100 to be determined depending on the initial short circuit current of the bottom cell, light-induced degradation ratio is reduced and stabilized efficiency after light illumination is increased. That is, since the actual operating temperature of the photovoltaic module 100 is relatively low, it is more possible to improve a power generation performance by reducing the light-induced degradation ratio than to deteriorate the power generation performance by the temperature coefficient. Particularly, a fill factor is less degraded by light illumination so that an outdoor power generation performance is excellent in an environment in which an ambient temperature is lower than 25° C. of STC.

When NOCT of the photovoltaic module 100 according to the embodiment of the present invention is equal to or higher than 40° C. and the photoelectric conversion layer of the photovoltaic module 100 includes two stacked unit cells, the initial short circuit current of the top cell under STC should be the same as or smaller than the initial shun circuit current of the bottom cell.

Here, according to the embodiment of the present invention, it is recommended that an initial short circuit current density of the top cell under STC is less than the initial short circuit current density of the bottom cell (J_{SC, initial top}<J_{SC, initial bottom}). In particular, it is recommended that a difference between the initial, short circuit current density of the bottom cell and the initial short circuit current density of the top cell is equal to or greater than 0.2 mA/cm² and is equal to or less than 1.5 mA/cm².

In order that the initial short circuit current of the photovoltaic module 100 is determined by the initial shun circuit current of the top cell and the small temperature coefficient is guaranteed, it is necessary that the difference is maintained greater than or equal to 0.2 mA/cm². When the difference is maintained less than or equal to 1.5 mA/cm², it is possible to prevent the stabilized efficiency of the photovoltaic module 100 from being excessively reduced.

When NOCT of the photovoltaic module 100 according to the embodiment of the present invention is less than 40° C. and the photoelectric conversion layer of the photovoltaic module 100 includes the two stacked unit cells, the initial short circuit current of the bottom cell under STC should be the same as or smaller than the initial short circuit current of the top cell.

Here, the initial short circuit current density of the bottom cell according to the embodiment of the present invention may be equal to or less than the initial short circuit current density of the top cell (J_{SC, initial top}≧J_{SC, initial bottom}). It is preferable that the difference between the initial short circuit current density of the top cell and the initial short circuit current density of the bottom cell is equal to or less than 2 mA/cm². When the difference is maintained less than or equal to 2 mA/cm², it is possible to prevent an open circuit voltage V_{OC} and fill factor of the photovoltaic module 100 from being excessively reduced by serious short circuit current mismatch.

When NOCT of the photovoltaic module 100 according to the embodiment of the present invention is equal to or higher than 40° C. and the photoelectric conversion layer of the photovoltaic module 100 includes three stacked unit cells, the initial short circuit current of the top cell under STC should be the same as or smaller than the initial short circuit currents of the middle cell and the bottom cell.

Here, according to the embodiment of the present invention, it is recommended that the initial short circuit current density of the top cell is the least compared with the initial short circuit current densities of the bottom cell and the middle cell (J_{SC, initial top}<J_{SC, initial bottom} OR J_{SC, initial middle}). Here, since the short circuit currents of the middle cell and the bottom cell are less degraded by light than the short circuit current of the top cell, which one is greater than the other between the initial short circuit currents of the middle cell and the bottom cell is not significant. In particular, it is recommended that a difference between the greatest initial short circuit current density and the initial short circuit current density of the top cell is equal to or greater than 0.2 mA/cm² and is equal to or less than 1.5 mA/cm².

In order that the short circuit current of the photovoltaic module 100 is determined by the initial short circuit current of the top cell and the small temperature coefficient is guaranteed, it is necessary that the difference is maintained greater than or equal to 0.2 mA/cm². When the difference is maintained less than or equal to 1.5 mA/cm², it is possible to prevent the stabilized efficiency of the photovoltaic module 100 from being excessively reduced.

When NOCT of the photovoltaic module 100 according to the embodiment of the present invention is less than 40° C. and the photoelectric conversion layer of the photovoltaic module 100 includes the three stacked unit cells, the initial short circuit current of the bottom cell under STC should be the same as or smaller than the initial short circuit currents of the top cell and the middle cell.

Here, it is preferable that the initial short circuit current density of the bottom cell according to the embodiment of the present invention is equal to or less than the initial short circuit current density of the middle cell, and the initial short circuit current density of the middle cell is less than the initial short circuit current density of the top cell (J_{SC, initial bottom}≦J_{SC, initial middle}<J_{SC, initial top}). Since the short circuit current of the top cell is more degraded by light than the short circuit current of the middle cell, it is preferable that the initial short circuit current density of the top cell is the greatest. Here, it is preferable that the difference between the initial short circuit current density of the top cell and the initial short circuit current density of the bottom cell is equal to or greater than 0.2 mA/cm² and is equal to or less than 2 mA/cm².

In order that the initial short circuit current of the photovoltaic module 100 is determined by the initial short circuit current of the bottom cell and a small light-induced degradation ratio is guaranteed, it is necessary that the difference is maintained greater than or equal to 0.2 mA/cm². When the difference is maintained less than or equal to 2 mA/cm², it is possible to prevent the open circuit voltage V_{OC} and fill factor of the photovoltaic module 100 from being excessively reduced by serious short circuit current mismatch.

The short circuit current of the photovoltaic module 100, which is for the current matching design of the photovoltaic module 100 according to the embodiment of the present invention, may be measured under STC. In the photovoltaic module 100 according to the embodiment of the present invention, it is necessary to control the short circuit current of each unit cell for the purpose of the current matching. Here, the short circuit current of each unit cell can be controlled by adjusting the thickness and/or the optical band gap of the light absorber included in each unit cell. For example, the short circuit current of the unit cell may be increased with the increase in the thickness of the light absorber and with the decrease in the optical band gap.

As described above, the current matching design is performed according to NOCT of the photovoltaic module 100, which is measured under SRE similar to an environment in which the photovoltaic module 100 is actually installed, so that the photovoltaic module 100 having a desired performance in a practical environment can be provided.

While the embodiment of the present invention has been described with reference to the accompanying drawings, it can be understood by those skilled in the art that the present invention can be embodied in other specific forms without departing from its spirit or essential characteristics. Therefore, the foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures.

What is claimed is:

1. A photovoltaic module which comprises a plurality of stacked unit cells and is encapsulated by an encapsulant,
wherein a nominal operating, cell temperature of the photovoltaic module is equal to or greater than a predetermined value, and
wherein the photovoltaic module is designed such that an initial short circuit current of the photovoltaic module under standard test conditions is determined depending on an initial short circuit current of a top cell among the plurality of the unit cells.

2. The photovoltaic modulo of claim 1, wherein the predetermined value is 40° C.

3. The photovoltaic module of claim 1, wherein the plurality of the unit cells are comprised of the top cell and a bottom cell, wherein an initial short circuit current density of the bottom cell is greater than an initial short circuit current density of the top cell, and wherein a difference between the initial short circuit current density of the bottom cell and the initial short circuit current density of the top cell is equal to or greater than 0.2 mA/cm² and is equal to or less than 1.5 mA/cm².

4. The photovoltaic module of claim 1, wherein the plurality of the unit cells are comprised of the top cell, a middle cell and a bottom cell, wherein a greatest initial short circuit current density among initial short circuit current densities of the middle cell and the bottom cell is greater than an initial short circuit current density of the top cell, and wherein a difference between the greatest initial short circuit current density and the initial short circuit current density of the top cell is equal to or greater than 0.2 mA/cm² and is equal to or less than 1.5 mA/cm².

5. The photovoltaic module of claim 2, wherein the plurality of the unit cells are comprised of the top cell and a bottom cell, wherein an initial short circuit current density of the bottom cell is greater than an initial short circuit current density of the top cell, and wherein a difference between the initial short circuit current density of the bottom cell and the initial short circuit current density of the top cell is equal to or greater than 0.2 mA/cm² and is equal to or less than 1.5 mA/cm².

6. The photovoltaic module of claim 2, wherein the plurality of the unit cells are comprised of the top cell, a middle cell and a bottom cell, wherein a greatest initial short circuit current density among initial short circuit current densities of the middle cell and the bottom cell is greater than an initial short circuit current density of the top cell, and wherein a difference between the greatest initial short circuit current density and the initial short circuit current density of the top cell is equal to or greater than 0.2 mA/cm² and is equal to or less than 1.5 mA/cm².

7. A photovoltaic module which comprises a plurality of stacked unit cells and is encapsulated by an encapsulant,
wherein a nominal operating cell temperature of the photovoltaic module is lower than and not equal to a predetermined value, and
wherein the photovoltaic module is designed such that an initial short circuit current of the photovoltaic module under standard test conditions is determined depending on an initial short circuit current of a bottom cell among the plurality of the unit cells.

8. The photovoltaic module of claim 7, wherein the predetermined value is 40° C.

9. The photovoltaic module of claim 7, wherein the plurality of the unit cells are comprised of the bottom cell and a top cell, wherein an initial short circuit current density of the top cell is greater than an initial short circuit current density of the bottom cell, and wherein a difference between the initial short circuit current density of the bottom cell and the initial short circuit current density of the top cell is equal to or greater than 0 mA/cm² and is equal to or less than 2 mA/cm².

10. The photovoltaic module of claim 7, wherein the plurality of the unit cells are comprised of the bottom cell, a middle cell and a top cell, wherein an initial short circuit current density of the top cell is greater than an initial short circuit current density of the middle cell, wherein the initial short circuit current density of the top cell is greater than an initial short circuit current density of the bottom cell, and wherein a difference between the initial short circuit current density of the top cell and the initial short circuit current density of the bottom cell is equal to or greater than 0.2 mA/cm² and is equal to or less than 2 mA/cm².

11. The photovoltaic module of claim 8, wherein the plurality of the unit cells are comprised of the bottom cell and a top cell wherein an initial short circuit current density of the top cell is greater than an initial short circuit current density of the bottom cell, and wherein a difference between the initial short circuit current density of the bottom cell and the initial short circuit current density of the top cell is equal to or greater than 0 mA/cm² and is equal to or less than 2 mA/cm².

12. The photovoltaic module of claim 8, wherein the plurality of the unit cells are comprised of the bottom cell, a middle cell and a top cell, wherein an initial short circuit current density of the top cell is greater than an initial short circuit current density of the middle cell, wherein the initial short circuit current density of the top cell is greater than an initial short circuit current density of the bottom cell, and wherein a difference between the initial short circuit current density of the top cell and the initial short circuit current density of the bottom cell is equal to or greater than 0.2 mA/cm² and is equal to or less than 2 mA/cm².
